(19) United States
(12) Patent Application Publication
(10) Pub. No.: US 2014/0167099 A1
(43) Pub. Date: Jun. 19, 2014

(54) INTEGRATED CIRCUIT INCLUDING SILICON CONTROLLED RECTIFIER

(71) Applicant: Markus Paul Josef Mergens, Kirchseeon (DE)

(72) Inventor: Markus Paul Josef Mergens, Kirchseeon (DE)

(73) Assignee: QPX GmbH, Kirchseeon (DE)

(21) Appl. No.: 14/004,182

(22) PCT Filed: Mar. 9, 2012
(86) PCT No.: PCT/EP2012/001074

§ 371 Date: Nov. 7, 2013

Related U.S. Application Data
(60) Provisional application No. 61/451,356, filed on Mar. 10, 2011.

(51) Int. Cl. H01L 29/87

(52) U.S. Cl. CPC H01L 29/87
USPC 257/109

(57) ABSTRACT

An integrated circuit includes a protected circuit. The integrated circuit further includes a silicon controlled rectifier including a sequence of a first p-type region, a second n-type region, a third p-type region and a fourth n-type region. The first n-type region is electrically coupled to the protected circuit. The integrated circuit further includes a first pn junction diode including a first semiconductor zone and one of the group including the second n-type region and the third p-type region as a second semiconductor zone. A conductivity type of the first semiconductor zone is opposite to the conductivity type of the second semiconductor zone. The integrated circuit further includes a first trigger circuit electrically coupled to the first semiconductor zone.

### BACKGROUND

Silicon Controlled Rectifiers (SCRs) or Thyristors have been widely used as on-chip Electrostatic Discharge (ESD) protection elements since the early times of semiconductor integrated circuits because of their superior ESD behavior. SCRs allow accomplishing large failure currents per area, low dynamic on-resistances, and linear width scaling of the ESD performance as a result of the regenerative conduction mechanism with double-carrier injection.

High ESD demands typically requested for system-pins (i.e. pins directly interfacing to the outside world with 8 kV-HBM or 8 kV-“GUN” specifications according to IEC-61400-4-2 require ESD on-chip elements with a current conduction capability above e.g., Iesd>16 A for 100 ns-Transmission Line Pulses (TLP). For these applications, SCRs can offer area efficient ESD current shunts while limiting the ESD voltage sufficiently below the Integrated Circuit (IC) damage levels.

High-voltage technologies, e.g., High Voltage-Complementary MOS (HV-CMOS) or Bipolar-CMOS-Double diffused MOS (BCD) often exhibit ESD sensitive high-voltage NMOS/DMOS transistors. This ESD sensitivity is caused by “strong” voltage snapback at inherent parasitic NPN turn-on as demonstrated by M. Mergens, W. Wilkening, S. Mettler, H. Wolf, A. Stricker, W. Fichtner, Analysis of 40V-LDMOS Power Devices under ESD Stress Conditions. IEEE Trans. Elect. Dev. Vol. 47, No. 11, pp. 2128-2137, 2000. Such a high-voltage snapback operation frequently results in a direct degradation or failure of the transistor. In particular HV-CMOS technologies lack suitable ESD protection elements due to weak lateral (parasitic) bipolar/diodes available as ESD conduction paths only. Here, high-voltage SCR-type protection devices can be feasible and efficient ESD protection solutions.

FIG. 1 depicts a typical current vs. voltage (IV) characteristic of an SCR including the relevant IV parameters: BV (breakdown voltage), It1 (SCR triggering current), Vt1 (SCR trigger voltage), Vh (SCR holding voltage), Ron (dynamic on-resistance), It2 (SCR failure current), Vt2 (SCR failure voltage).

Some implementations with external trigger devices/circuitry (on-chip and external to the SCR) and means to avoid SCR latch-up during normal operation conditions are known. The external triggering circuit activates the SCR latch-up at the onset of an ESD event while subsequently shunting the ESD current and clamping the ESD voltage to safe values. In the IC, such an ESD protection device is typically connected between an IC pad and a supply/ground line.

U.S. Pat. No. 5,012,317 discloses an ESD protection device including a PNPN type device disposed between the input pad and ground. A first P-layer is disposed in an N-type well which is formed in a P-type layer. A second N-region is provided for connection to ground. This provides an SCR which can be turned on by avalanching the intermediate PN junction to place the device in a regenerative mode for positive transients. For negative transients, a P+ region is provided in P-layer to bypass a PN junction and a N+ region is defined in the N-type region to bypass PN junction. This provides a forward-biased diode for the negative transient.

U.S. Pat. No. 4,870,530 describes a protective circuit for bipolar integrated circuits to prevent inadvertent damage caused by electrostatic discharge. The protective circuit includes a plurality of clamping networks. Each of the plurality of clamping networks is connected between a corresponding one of a number of external input/output pins of the integrated circuit and a common bus line which is connected to an external substrate pin. Each of the plurality of clamping networks includes a silicon-controlled rectifier, a diode, a first resistor and a second resistor. When any one of the number of external input/output pins receives a voltage higher than a predetermined value and any remaining one of the external input/output pins contacts a ground potential, a discharge path is formed by a single silicon-controlled rectifier and a single diode so as to protect an internal circuit portion.

A semiconductor device according to U.S. Pat. No. 4,694,315 includes a semiconductor circuit of CMOS type and an overvoltage protective circuit integrated therewith. The CMOS circuit and the overvoltage protective circuit are formed in one and the same substrate. The device has a contact electrically connected to the substrate. The CMOS circuit has a plurality of inputs. Between each input and the contact connected to the substrate, there is formed and connected in antiparallel a thyristor and a diode. Each thyristor has a firing circuit for ignition of the thyristor at a voltage level which is internally predetermined by the overvoltage protective circuit. In this way, an overvoltage occurring between an arbitrary pair of inputs will cause ignition of the thyristors of the overvoltage protective circuit and short-circuit of the inputs, which efficiently protects the CMOS circuit against overvoltages.

U.S. Pat. No. 6,791,122 discloses a silicon controlled rectifier electrostatic discharge protection circuit with external on-chip triggering and compact internal dimensions for fast triggering. The ESD protection circuit includes a silicon controlled rectifier (SCR) having an anode coupled to the protected circuitry and a cathode coupled to ground, where the cathode has at least one high-doped region. At least one trigger-tap is disposed proximate to the at least one high-doped region and an external on-chip triggering device is coupled to the trigger-tap and the protected circuitry.

U.S. Pat. No. 6,803,633 relates to an electrostatic discharge (ESD) protection device having high holding current for latch-up immunity. The ESD protection circuit is formed in a semiconductor integrated circuit having protected circuitry. The ESD protection device includes a silicon controlled rectifier coupled between a protected supply line of the IC and ground. A trigger device is coupled from the supply line to a first gate of the SCR, and a first substrate resistor is coupled between the first gate and ground. A first shunt resistor is coupled between the first gate and ground, wherein the shunt resistor has a resistance value lower than the substrate resistor.

### SUMMARY

It is an object to provide a compact and reliable protection concept for an IC.

For these and other reasons there is a need for the present invention.

The above object is solved by the integrated circuit of claim 1. Advantageous further embodiments are defined in the dependent claims.

According to an embodiment of an integrated circuit, the integrated circuit includes a protected circuit. The integrated circuit further includes a silicon controlled rectifier including a sequence of a first p-type region, a second n-type region, a third p-type region and a fourth n-type region. The first p-type region is electrically coupled to the protected circuit. The integrated circuit further includes a first pn junction diode including a first semiconductor zone and one of the group including the second n-type region and the third p-type region as a second semiconductor zone. A conductivity type of the first semiconductor zone is opposite to the conductivity type of the second semiconductor zone. The integrated circuit further includes a first trigger circuit electrically coupled to the first semiconductor zone.

Those skilled in the art will recognize additional features and advantages upon reading the following detailed description, and on viewing the accompanying drawings.

### BRIEF DESCRIPTION OF THE DRAWINGS

The accompanying drawings are included to provide a further understanding of the present invention and are incorporated in and constitute a part of this specification. The drawings illustrate embodiments of the present invention and together with the description serve to explain principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts. The features of the various illustrated embodiments can be combined unless they exclude each other.

Embodiments are depicted in the drawings and are detailed in the description which follows.

FIG. 1 is a schematic illustration of a typical IV characteristic of an SCR.

FIG. 2A illustrates one embodiment of a circuit diagram including a protected circuit protected via an SCR and a diode sharing an n-type semiconductor zone.

FIG. 2B illustrates one embodiment of a circuit diagram including a protected circuit protected via an SCR and a diode sharing a p-type semiconductor zone.

FIG. 3 illustrates one embodiment of a circuit diagram including a protected circuit protected via an SCR triggered via a first trigger circuit electrically coupled to a first trigger protection at a PNP side of the SCR and triggered via a second trigger circuit electrically coupled to a second trigger protection at an NPN side of the SCR.

FIG. 4 illustrates one embodiment of a circuit diagram including a protected circuit protected via an SCR triggered simultaneously via an NPN side and a PNP side of the SCR.

FIGS. 5 to 7B illustrate schematic cross-sections of SCR and trigger protection(s) according to embodiments.

FIGS. 8A to 8D illustrate embodiments of elements of trigger circuits.

FIGS. 9A to 9D illustrate schematic circuit diagrams of trigger circuits triggering SCRs including trigger protection(s).

FIG. 10 illustrates one embodiment of an IV characteristic of an HV-NMOS with trigger circuit and operation of trigger protection.

FIG. 11 illustrates one embodiment of an IV characteristic of a principle SCR with increased holding voltage.

FIG. 12 illustrates embodiments of increasing the holding voltage of an SCR by adding series elements.

FIG. 13 illustrates embodiments of holding voltage elements including (parasitic) bipolar transistors.

FIG. 14 illustrates one embodiment of an IV characteristic for increasing the trigger current It1 of an SCR above the level of latch-up current injection I(latch-up).

FIG. 15 illustrates one embodiment of a robust parallel trigger shunt configured to increase It1.

FIG. 16 illustrates schematic circuit diagrams of trigger schemes for SCRs including trigger protection and trigger shunt.

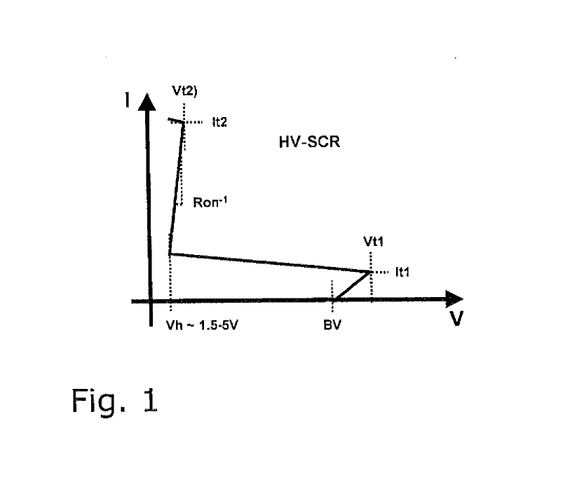

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, “over”, “above”, “below”, etc., is used with reference to the orientation of the Figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. For example, features illustrated or described as part of one embodiment can be used on or in conjunction with other embodiments to yield yet a further embodiment. It is intended that the present invention includes such modifications and variations. The embodiments are described using specific language which should not be construed as limiting the scope of the appending claims. The drawings are not scaled and are for illustrative purposes only. For clarity, the same elements or manufacturing processes have been designated by the same references in the different drawings if not stated otherwise.

The terms “lateral” and “horizontal” as used in this specification intends to describe an orientation parallel to a first surface of a semiconductor substrate or semiconductor body. This can be for instance the surface of a wafer or a die.

The term “vertical” as used in this specification intends to describe an orientation which is arranged perpendicular to the first surface of the semiconductor substrate or semiconductor body.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together, e.g., a connection via a metal and/or highly doped semiconductor.

In this specification, n-doped may refer to a first conductivity type while p-doped is referred to a second conductivity type. It goes without saying that the semiconductor devices can be formed with opposite doping relations so that the first conductivity type can be p-doped and the second conductivity type can be n-doped. Furthermore, some Figures illustrate relative doping concentrations by indicating “−” or “+” next to the doping type. For example, “n⁻” means a doping concentration which is less than the doping concentration of an “n”-doping region while an “n⁺”-doping region has a larger doping concentration than the “n”-doping region. Indicating the relative doping concentration does not, however, mean that doping regions of the same relative doping concentration have the same absolute doping concentration unless otherwise stated. For example, two different n⁺-doped regions can have different absolute doping concentrations. The same applies, for example, to an n⁺-doped and a p⁺-doped region.

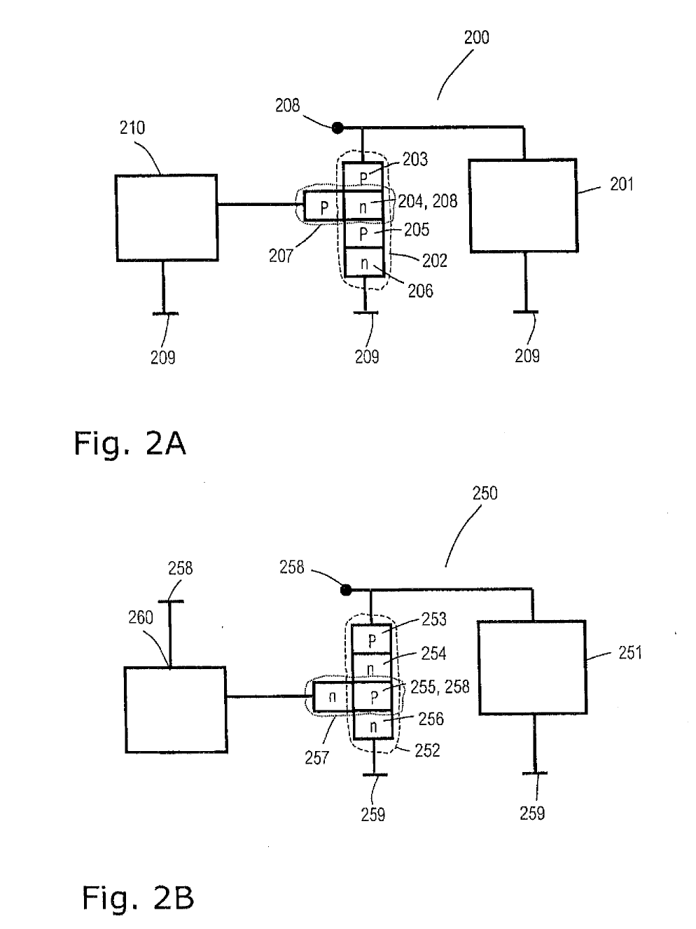

FIG. 2A illustrates one embodiment of an IC 200 including a protected circuit 201. The protected circuit 201 is protected via a SCR 202. The SCR 202 includes a first p-type region 203, a second n-type region 204, a third p-type region 205 and a fourth n-type region 206. A pn junction diode 207 includes an anode zone 207 and the second n-type region 204 as a cathode zone 208. Thus, the second n-type region 204 is shared between the SCR 202 and pn junction diode 207. In other words, the second n-type region 204 fulfills a double-function and acts as an active element of both the SCR 202 and the pn junction diode 207. As an example, the second n-type region may be an n-well (also denoted NW herein). The second n-type region may also include a plurality of n-type zones adjoining each other or overlapping with each other to form one continuous n-type region.

The protected circuit 201 may be any circuit block electrically coupled between a first terminal 208 and a second terminal 209. As an example, the first terminal 208 may be any of a supply terminal, an input terminal and an output terminal. As a further example, the second terminal 209 may be a ground terminal.

A trigger circuit 210 is electrically coupled to the anode zone 207 of the pn junction diode 207.

Coupling the pn junction diode 207 between the trigger circuit 210 and the SCR 202 allows reducing a voltage drop across the trigger circuit 210 and thereby avoiding damage of the trigger circuit 210. Further, the capacitance into the trigger circuit 210 may be reduced, thereby acting against unintended SCR triggering by dV/dt. The arrangement illustrated in FIG. 2A allows compact and reliable protection of the protected circuit 201.

FIG. 2B illustrates one embodiment of an IC 250 including a protected circuit 251. The protected circuit 251 is protected via a SCR 252. The SCR 252 includes a first p-type region 253, a second n-type region 254, a third p-type region 255 and a fourth n-type region 256. A pn junction diode 257 includes a cathode zone 257 and the third p-type region 255 as an anode zone 258. Thus, the third p-type region 255 is shared between the SCR 252 and pn junction diode 257. In other words, the third p-type region 255 fulfills a double-function and acts as an active element of both the SCR 252 and the pn junction diode 257. As an example, the third p-type region may be a p-well (also denoted PW herein). The third p-type region may also include a plurality of p-type zones adjoining each other or overlapping with each other to form one continuous p-type region.

The protected circuit 251 may be any circuit block electrically coupled between a first terminal 258 and a second terminal 259. As an example, the first terminal 258 may be any of a supply terminal, an input terminal and an output terminal. As a further example, the second terminal 259 may be a ground terminal.

A trigger circuit 260 is electrically coupled to the cathode zone 257 of the pn junction diode 257.

Coupling the pn junction diode 257 between the trigger circuit 260 and the SCR 252 allows reducing a voltage drop across the trigger circuit 260 and thereby avoiding damage of the trigger circuit 260. Further, the capacitance into the trigger circuit 260 may be reduced, thereby acting against unintended SCR triggering by dV/dt. The arrangement illustrated in FIG. 2B allows compact and reliable protection of the protected circuit 251.

In the embodiment illustrated in FIG. 2A the trigger circuit 210 is electrically coupled to the second terminal 209. In the embodiment illustrated in FIG. 2B the trigger circuit 260 is electrically coupled to the first terminal 258. The trigger circuit 210 and/or the trigger circuit 260 may also be electrically coupled between the first and second terminals 208, 258, 209, 259. As a further example, each of the trigger circuits 210, 260 may be electrically coupled to any one of ground and supply or between ground and supply.

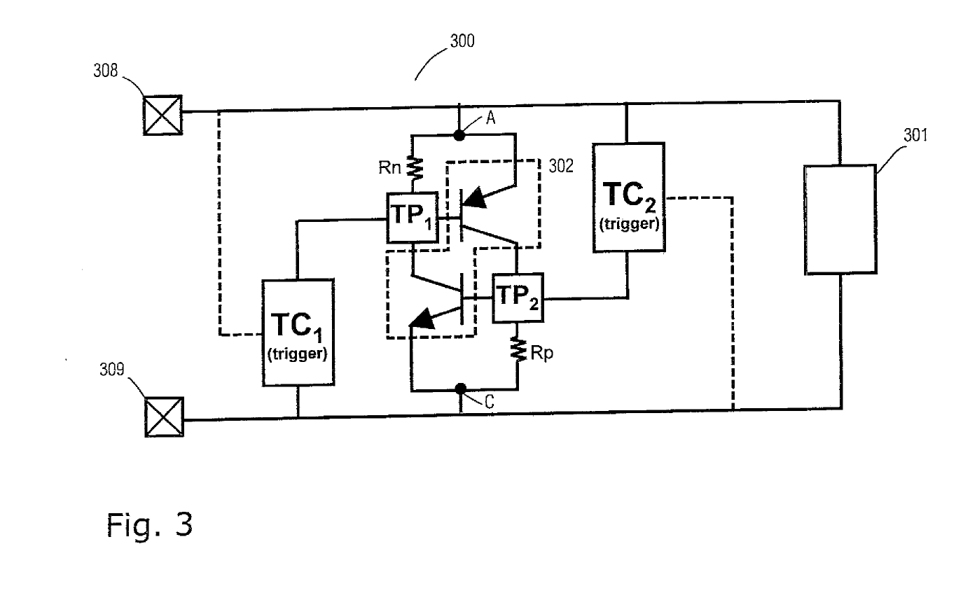

FIG. 3 illustrates illustrates one embodiment of an IC 300 including a protected circuit 301. The protected circuit is electrically coupled between a first terminal 308 and a second terminal 309.

An SCR 302 is electrically coupled between the first terminal 308 and the second terminal 309. An anode terminal A of the SCR 302 is electrically coupled to the protected circuit 301.

A first trigger circuit TC₁ is electrically coupled to an integrated first trigger protection TP₁ to trigger the SCR 302 at a well-defined voltage level by current conduction through the first trigger protection TP₁ while the trigger protection TP₁ limits the voltage drop across the first trigger circuit TC₁ and the capacitance seen by the SCR emitters. The integrated first trigger protection TP₁ is formed by at least one pn junction formed in conjunction with an n-well of the SCR 302 or an adjacent n-well coupled to the SCR-well of same doping type, thereby reducing the voltage drop across the first trigger circuit TC₁ and avoiding damage of the first trigger circuit TC₁. Further, the capacitance into the first trigger circuit TC₁ is reduced to act against unintentional triggering of the SCR 302 by dV/dt. An external resistor Rn may be electrically coupled between the first trigger protection TP₁ and the anode terminal A.

A second trigger circuit TC₂ is electrically coupled to an integrated second trigger protection TP₂ to trigger the SCR 302 at a well-defined voltage level by current conduction through the second trigger protection TP₂ while the second trigger protection TP₂ limits the voltage drop across the first trigger circuit TC₂ and the capacitance seen by the SCR emitters. The integrated second trigger protection TP₂ is formed by at least one pn junction formed in conjunction with a p-well of the SCR 302 or an adjacent p-well coupled to the SCR-well of same doping type, thereby reducing the voltage drop across the trigger circuit TC₂ and avoiding damage of the second trigger circuit TC₂. Further, the capacitance into the second trigger circuit TC₂ is reduced to act against unintentional triggering of the SCR 302 by dV/dt. An external resistor Rp may be electrically coupled between the first trigger protection TP₁ and a cathode terminal C of the SCR 302.

The trigger circuits TC₁ and TC₂ may include different circuit elements. Likewise, the trigger protections TP₁ and TP₂ may include different circuit elements.

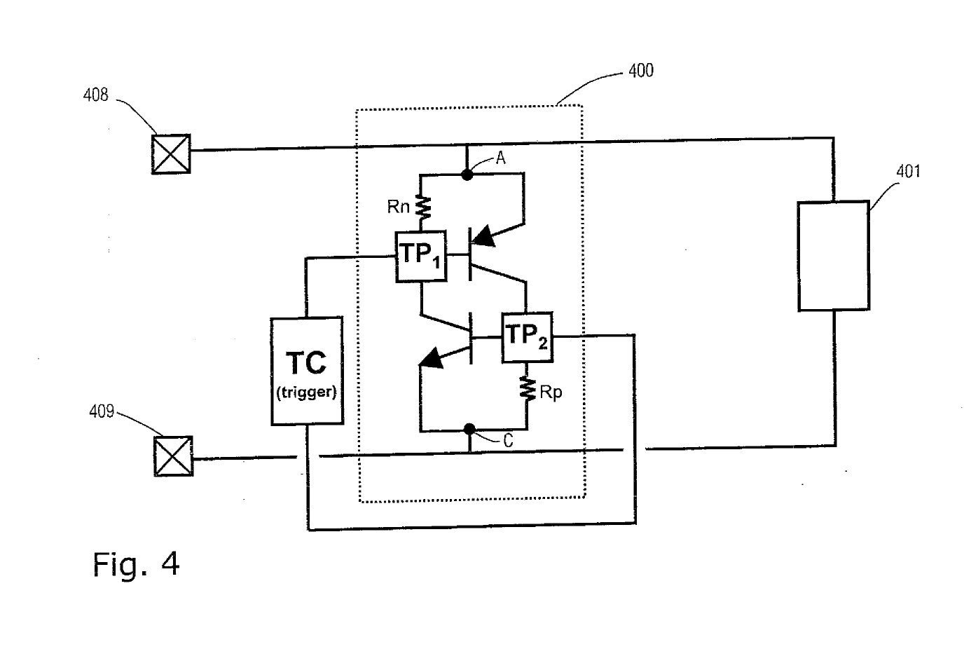

FIG. 4 illustrates another embodiment of an IC 400. Similar to the IC 300 illustrated in FIG. 3, the IC 300 includes a protected circuit 401, an SCR 402 electrically coupled between a first terminal 408 and a second terminal 409 and including an anode A and a cathode C, first and second trigger protections TP₁ and TP₂, and external resistors Rn and Rp.

The IC 400 further includes a trigger circuit TC electrically coupled between the first and second trigger protections TP₁, TP₂, respectively, for simultaneous triggering of the SCR 402.

The technical explanations in the following paragraph focus on PNP-side SCR triggering, while NPN-sided effects are working in a complementary fashion.

During an ESD event and SCR triggering, almost the full transient ESD voltage is also exposed to the trigger (and here trigger protection in series) through the SCR anode.

One purpose (besides the overall trigger cap reduction) of the trigger protection is to limit the voltage across and current through the potentially sensitive high-voltage element, e.g., formed by a HV-NMOS (e.g., a lateral DMOS) or a chain of small trigger elements. This is beneficial for several reasons, inter alia:
a) The HV-NMOS trigger element can be gate-biased during the onset of ESD (i.e. during the first few nanoseconds) to initiate MOS current conduction for SCR trigger. This will allow for accurate SCR Vt1 engineering. The technical challenge, however, is that HV-NMOS gate-bias can substantially reduce the snapback triggering voltage of the inherent parasitic NPN (as governed by the Transient Safe Operating Area TSOA). It is well known that often such a parasitic HV-NMOS snapback leads to direct damage as mentioned above. Reducing the voltage drop across the conduction device of trigger current, e.g., HVNMOS and limit the current by the trigger protection in series can effectively avoid such a parasitic turn-on and thus trigger damage.
b) Typically, HV-SCRs show a relatively slow response time during ESD, i.e. a relatively large turn-on time compared to the voltage rise time of the ESD event. This is due to the relatively large dimensions (e.g., anode-cathode spacing) required to achieve a high SCR blocking voltage during (high-voltage) normal operation. As a result of the relatively slow trigger speed, large trigger voltage overshoots can be generated before the SCR reaches the low resistive clamping state. Those voltage peaks will be exposed to a trigger device/circuit as well while the TP reduces the voltage exposure to the sensitive HV-MOS device in the TC.

The trigger circuit TC₁, TC₂, TC is activated during the onset of ESD to define the SCR trigger voltage. Once the SCR is latched, the TC is fully turned OFF and does not impact the electrical SCR behavior anymore, since the ESD voltage is clamped below the trigger voltage of the trigger circuit.

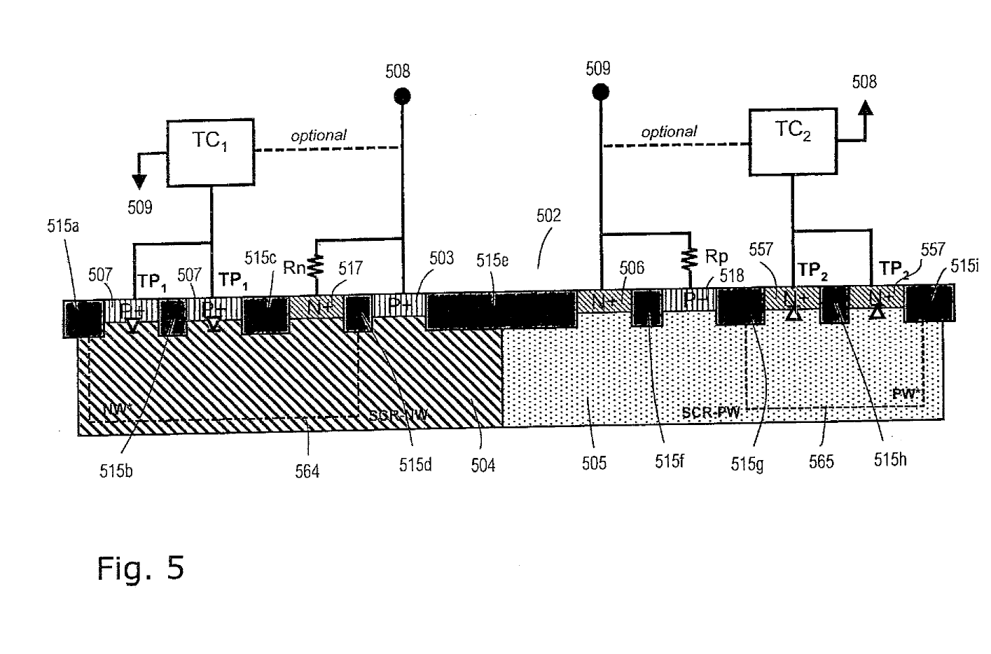

FIG. 5 illustrates one embodiment of a SCR 502 including trigger protection with trigger protection junctions TP₁, TP₂ (as indicated by the diode symbol) being integrated into the SCR 502. The trigger protections TP₁ include a p⁺-type zone 507 in an SCR n-well 504. According to other embodiments, the n-type region of the trigger protection TP₁ may include an n-well of the SCR 502 and a further n-well, e.g., n-well 564, or in one embodiment the further n-well to alter the integrated junction breakdown voltage. Also zener implants are feasible to achieve the purpose of a lowered breakdown if desired. Likewise, the trigger protections TP₂ include an n^{′}-type zone 557 in an SCR p-well 505. According to other embodiments, the p-type region of the trigger protection TP₂ may include a p-well of the SCR 502 and a further p-well, e.g., optional p-well 565, or in one embodiment the further p-well to alter the integrated junction breakdown voltage. Also zener implants are feasible to achieve the purpose of a lowered breakdown if desired. In the illustrated embodiment, two trigger protection junctions are inserted in each of the wells 504, 505, respectively, to reinforce the current capability during triggering. The SCR-wells are not necessarily adjoining as depicted in all figures. The SCR-wells may be spaced apart in a certain distance with the base material in between (e.g., substrate, epi).

The SCR 502 further includes an anode emitter 503, a cathode emitter 506, an n⁺-type contact zone 517 electrically coupled to the anode emitter 503 via an external resistor Rn, a p⁺-type contact zone 518 electrically coupled to the cathode emitter 506 via an external resistor Rp, an anode terminal 508 that is e.g., electrically coupled to any of a supply terminal, an input terminal and an output terminal, a cathode terminal 509 that is electrically coupled to e.g., a ground terminal, and insulating regions 515a . . . 515i electrically insulating neighboring semiconductor regions. As an example, each or some of the insulating regions 515a . . . 515i may include shallow trench isolation (STI).

During the onset of ESD, a trigger circuit TC₁ (TC₂) pulls the external terminal of TP₁ (TP₂) to a lower (higher) potential. Thus, TP₁ (TP₂) breaks down and the SCR n-well 504 (SCR p-well 505) is also pulled to a lower (higher) potential. This allows the anode emitter 503 (cathode emitter 506) to inject minority carriers into the PNP (NPN) base, i.e. the n-well 504 (p-well 505).

In one embodiment during the trigger event, the integrated junction limits the transient voltage exposed to the trigger circuit TC₁, TC₂ thus protecting it from being damaged. Most of the embodiments illustrated herein illustrate a symmetrical trigger implementation for the sake of generalization as mentioned above.

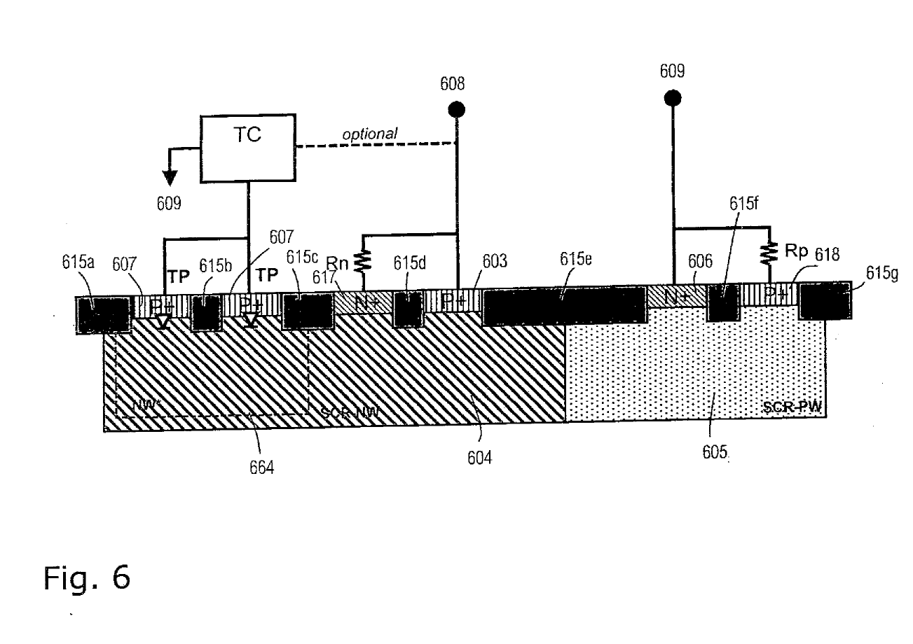

The trigger implementation may be and is typically asymmetrical meaning only one well of the SCR is coupled to a trigger circuit through the trigger protection. This is demonstrated in FIG. 6 illustrating an SCR 602 triggered by a trigger circuit TC, an anode emitter 603, an SCR n-well 604, an SCR p-well 605, a cathode emitter 606, an n⁺-type contact zone 617 electrically coupled to the anode emitter 603 via an external resistor Rn, a p⁺-type contact zone 618 electrically coupled to the cathode emitter 606 via an external resistor Rp, an anode terminal 608 that is e.g., electrically coupled to any of a supply terminal, an input terminal and an output terminal, a cathode terminal 609 that is electrically coupled to e.g., a ground terminal, and insulating regions 615a . . . 615g electrically insulating neighboring semiconductor regions. As an example, each or some of the insulating regions 615a . . . 615g may include shallow trench isolation (STI).

A trigger protection TP includes a p⁺-type zone 607 in the SCR n-well 604. According to other embodiments, the n-type region of the trigger protection TP may include an n-well of the SCR 602 and a further n-well, e.g., n-well 664, or in one embodiment the further n-well to alter the integrated junction breakdown voltage. Also zener implants are feasible to achieve the purpose of a lowered breakdown if desired.

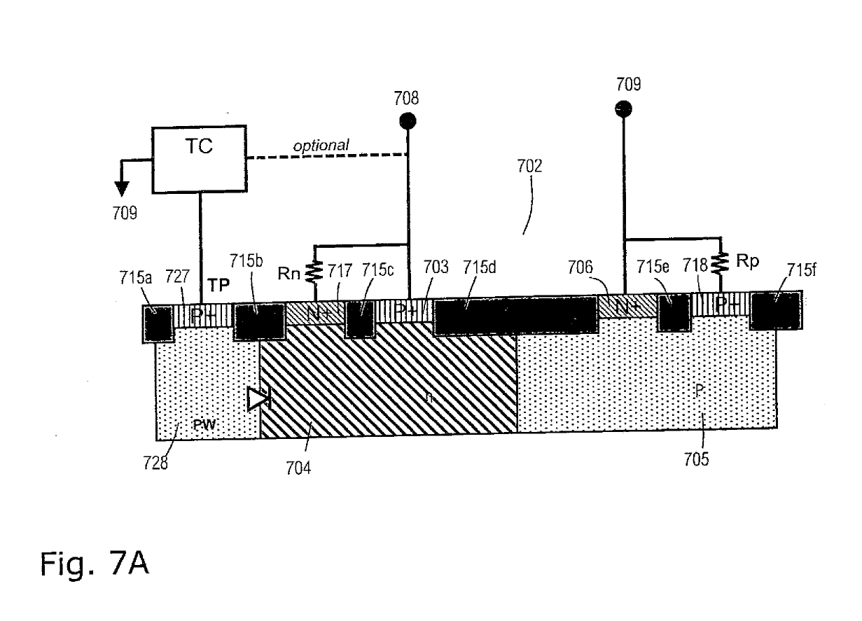

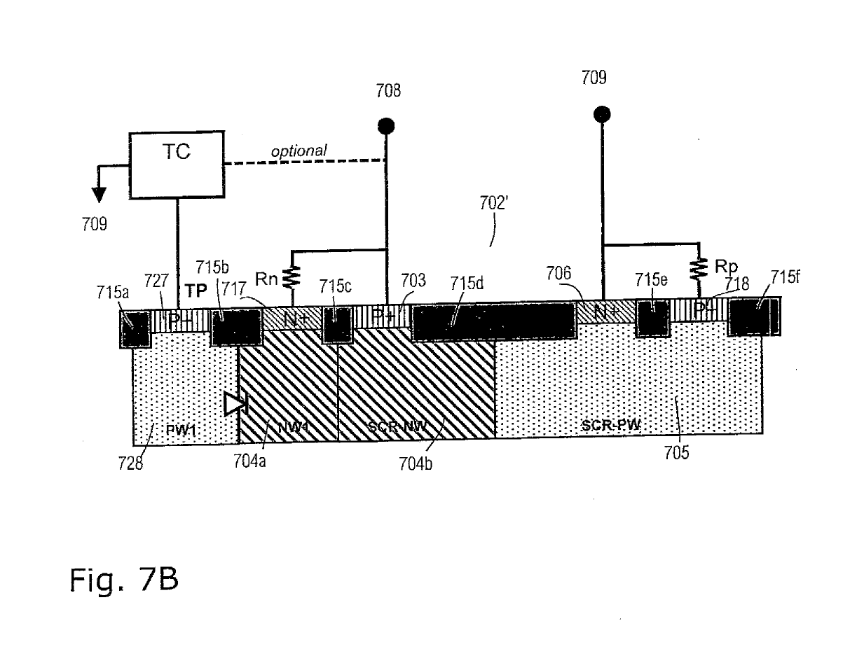

FIG. 7A illustrates SCR 702 triggered by a trigger circuit TC, an anode emitter 703, an SCR n-well 704, an SCR p-well 705, a cathode emitter 706, an n⁺-type contact zone 717 electrically coupled to the anode emitter 703 via an external resistor Rn, a p⁺-type contact zone 718 electrically coupled to the cathode emitter 706 via an external resistor Rp, an anode terminal 708 that is e.g., electrically coupled to any of a supply terminal, an input terminal and an output terminal, a cathode terminal 709 that is electrically coupled to e.g., a ground terminal, and insulating regions 715a . . . 715f electrically insulating neighboring semiconductor regions. As an example, each or some of the insulating regions 715a . . . 715f may include shallow trench isolation (STI).

A trigger protection TP includes a p⁺-type contact zone 727 in a p-well 728 constituting an anode of the trigger protection TP. The SCR n-well 704 is part of the cathode of the trigger protection TP.

An SCR 702′ similar to the SCR 702 is illustrated in FIG. 7B. The SCR 702′ includes a first n-well 704a and a second n-well 704b. The p-well 728 of the trigger protection TP adjoins the first n-well 704a. The n⁺-type contact zone 717 is formed in the first n-well 704a. The anode emitter 703 is formed in the second n-well 704b.

One benefit of the trigger protection is the fact, that the TP junction in series with the often large high-voltage trigger device substantially reduces the capacitance coupled to the SCR-wells by the trigger circuit. A large capacitance connected to the wells by the trigger may result in wrong transient SCR turn-on by injection of displacement current through the anode/cathode, respectively. So, the trigger protection also serves as dV/dt-trigger protection dropping most of the voltage across the relatively small TP capacitance. This avoids unwanted SCR turn on by voltage slew rates during normal operation conditions.

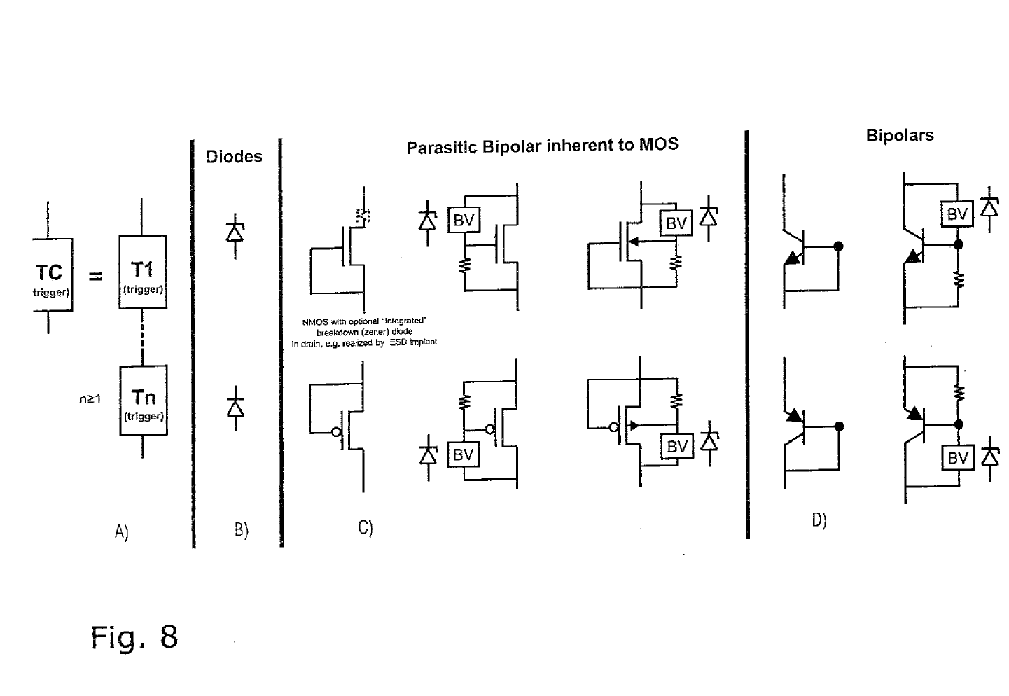

FIGS. 8A to 8D illustrate embodiments for different trigger elements that can be applied in the trigger circuit TC either as single elements or in series (see stacked elements T1 . . . Tn in FIG. 8A). Those elements are arranged to block during normal operation conditions (thus keeping the SCR off) while triggering sufficiently below the IC damage level under ESD stress conditions. Those elements include diodes, e.g., zener diodes (see FIG. 8B), parasitic bipolar transistors inherent to MOS devices (see FIG. 8C), and bipolar transistors (see FIG. 8D). The junction that determines the breakdown voltage of the elements illustrated in FIGS. 8C and 8D is denoted BV.

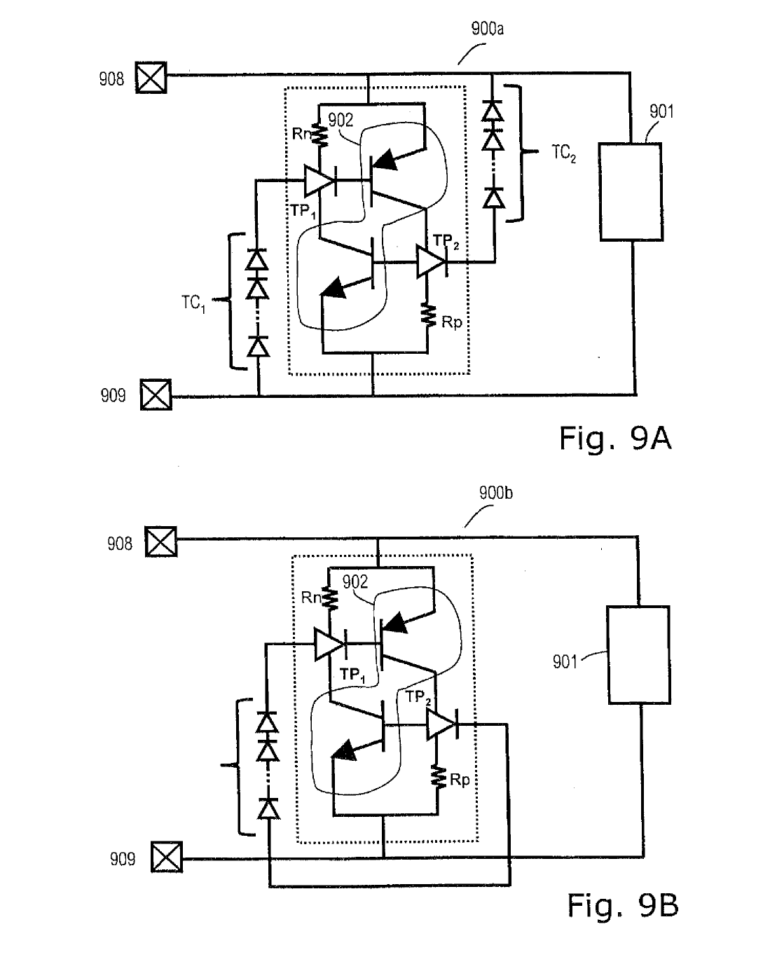

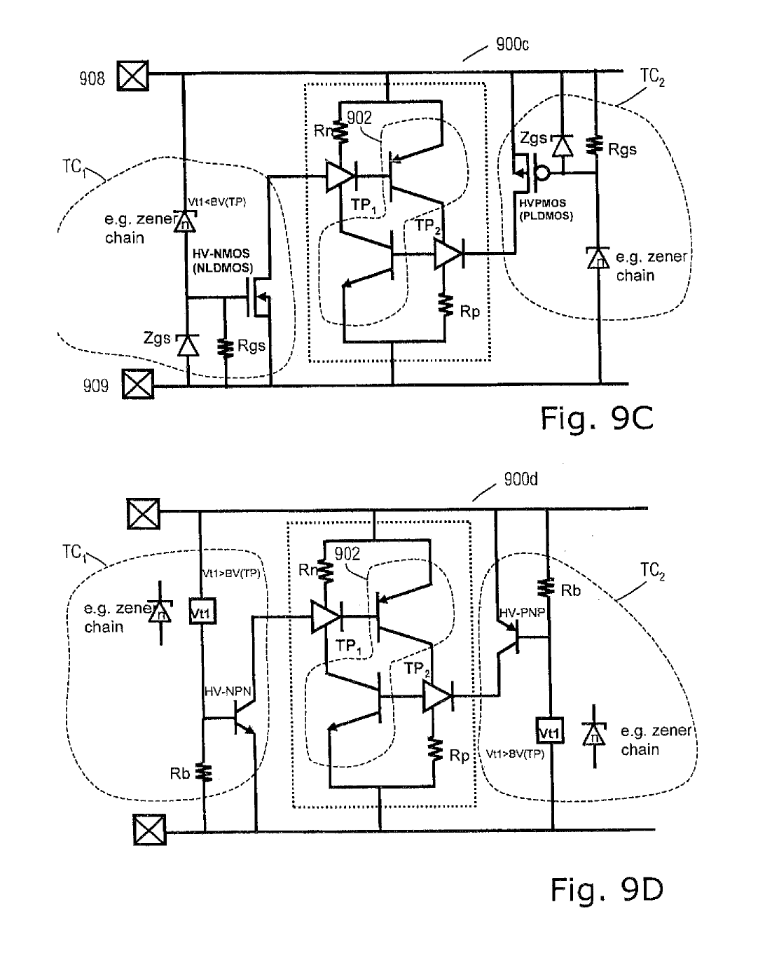

One embodiment of a trigger scheme using reverse trigger diodes in a series chain connection coupled to the trigger protection is illustrated in FIG. 9A. The circuit arrangement is similar to the embodiment illustrated in FIG. 3 and includes an IC 900a, a protected circuit 901, an SCR 902, integrated diodes as trigger protections TP₁ and TP₂, external resistors Rn and Rp, first and second terminals 908 and 909 and first and second trigger circuits TC₁ and TC₂. Each one of the trigger circuits TC1 and TC2 includes a number of diode junctions, e.g., one or a combination of the elements illustrated in FIGS. 8B to 8D. During ESD the stacked diode junctions break down and conduct the trigger current in avalanche into/out of the SCR 902. The number of trigger diodes in series determines the SCR trigger voltage to be designed above the corresponding operation voltage of the pin to be protected. The trigger diodes can be relatively small in size due to the trigger protection.

Another embodiment of a trigger scheme in an integrated circuit 900b is illustrated in FIG. 9B. The embodiment illustrated in FIG. 9B is similar to the embodiment illustrated in FIG. 4 and differs from the trigger scheme illustrated in FIG. 9A in that a trigger circuit TC is electrically coupled to the first and second trigger protections TP₁ and TP₂, thereby enabling simultaneous triggering in both SCR wells with dual-sided trigger circuit protection.

Further examples of trigger schemes are illustrated as integrated circuits 900c and 900d in FIGS. 9C and 9D, respectively, with actively controlled HV-MOS or HV-bipolar trigger circuits to be turned on at Vt1 during ESD. This turn-on is achieved by a trigger circuit/element (e.g., a zener chain) that biases the gate (base) of the HV-MOS (HV-BJT, HV-Bipolar Junction Transistor) after breakdown/trigger during ESD. The HV-MOS trigger elements are supposed to operate in MOS mode only while remaining safely within their Transient Safe Operating Area (TSOA) i.e. without triggering the parasitic bipolars. The trigger Vt1 can e.g., be defined by a zener-chain commonly used in active clamps. Rgs are pull-down/pull-up resistors turning the HV-MOS off during normal operation. Zgs is an optional zener gate clamp for gate-voltage limitation. Rtc1/Rtc2 can be applied optionally for increased voltage stability during normal operation.

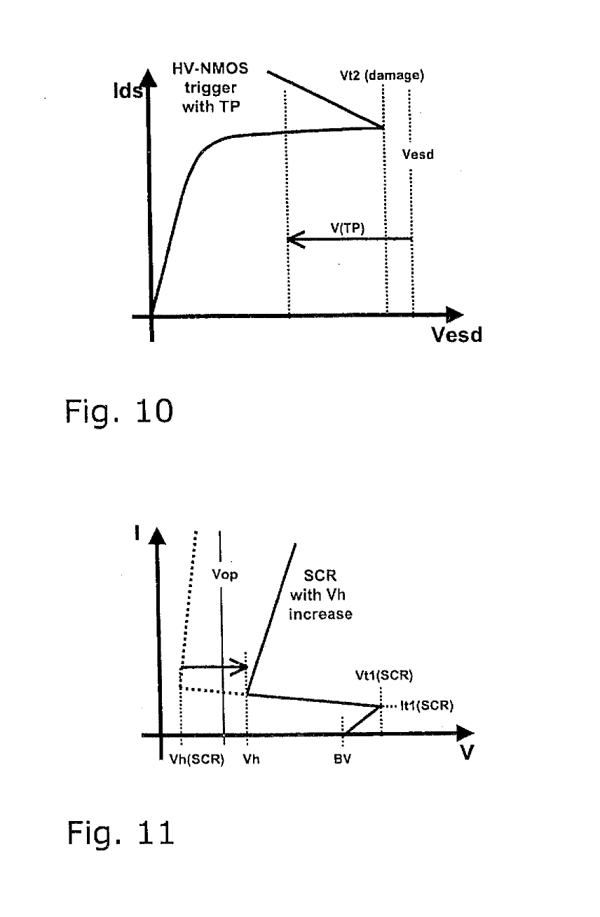

If the trigger voltage Vt1 defined by the MOS gate (BJT base) biasing scheme is larger than the breakdown voltage of the trigger protection, i.e. Vt1>BV(TP), the trigger voltage Vt1 can be adjusted largely independent from the BV(TP). Reason is that a) the trigger current of the SCR itself is relatively low and b) the current through the trigger MOS/BJT trigger device does only slightly depend on the voltage drop across the same, i.e. on the Vds or Vice. So, a voltage reduction by BV(TP) does not have such a significant impact on the trigger current injection capability of the MOS transistor once the gate is biased by the Vt1-circuit as indicated in FIG. 10 schematically illustrating a HV-NMOS IV characteristic up to ESD failure voltage Vt2. The trigger protection TP leads to an effective voltage stress reduction across the sensistive HV-NMOS trigger element without detrimental impact on trigger current supply.

One of the main issues applying SCRs for ESD protection in one embodiment in high-voltage technologies is the latch-up risk related to a too low holding voltage compared to the normal operation voltage. Therefore, it is generally desired to increase the holding voltage above the operation voltage as demonstrated in FIG. 11 illustrating an IV characteristic of an SCR with increased holding voltage. Several techniques are known including SCR core modifications. These can increase the holding voltage to some extent but on the other hand cause the excellent SCR ESD capabilities to diminish. Another alternative technique is adding appropriate series elements to be connected to the SCR on the anode and/or cathode side, respectively.

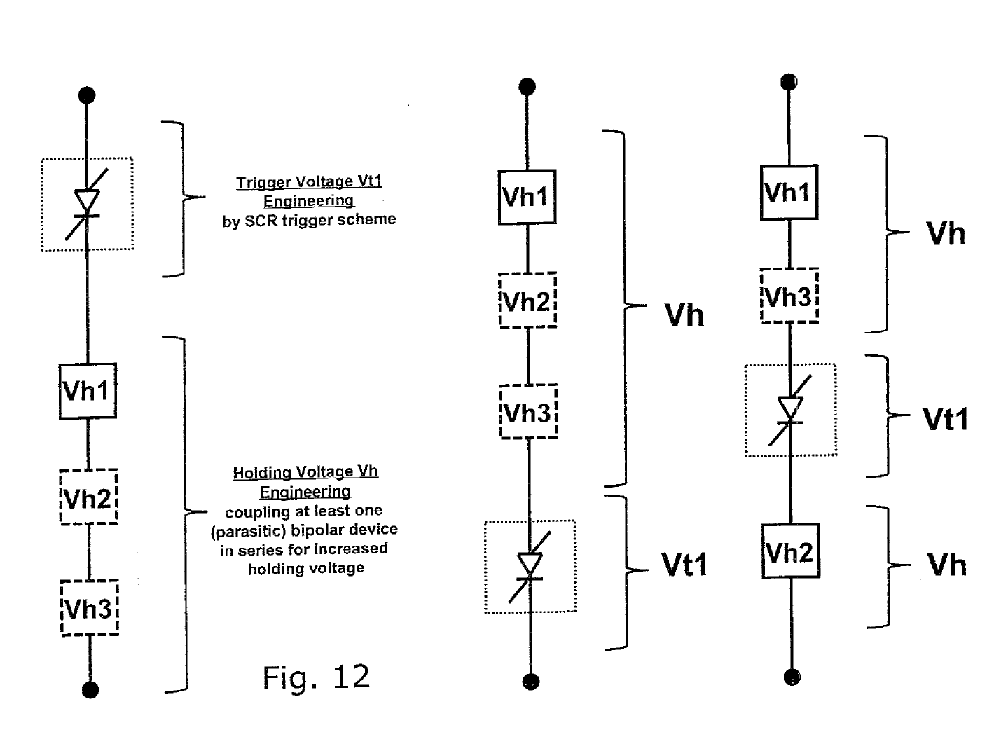

The holding voltage of an SCR ESD protection element can be increased by coupling at least one series element to the SCR as schematically illustrated in FIG. 12. In such a concept, the SCR will basically be engineered for an adequate trigger voltage (i.e. above the pin spec and below the IC damage level) whereas the series elements, e.g., Vh, Vh1 . . . Vh3, can be designed to increase the holding voltage above the operation voltage to avoid any latch-up issues. Embodiments of design and trigger schemes of the SCR illustrated in FIG. 12 are described in relation to the embodiments illustrated in FIGS. 2A to 9D.

As an example, in automotive applications one frequently encounters 45V pins while the battery voltage is at approximately 14V. Therefore, often it is sufficient to increase the holding voltage above these 14V (plus safety margin) to avoid any high battery current thru the ESD protection and thus damage of the device. The trigger voltage can be designed to meet the spec by using the techniques presented above.

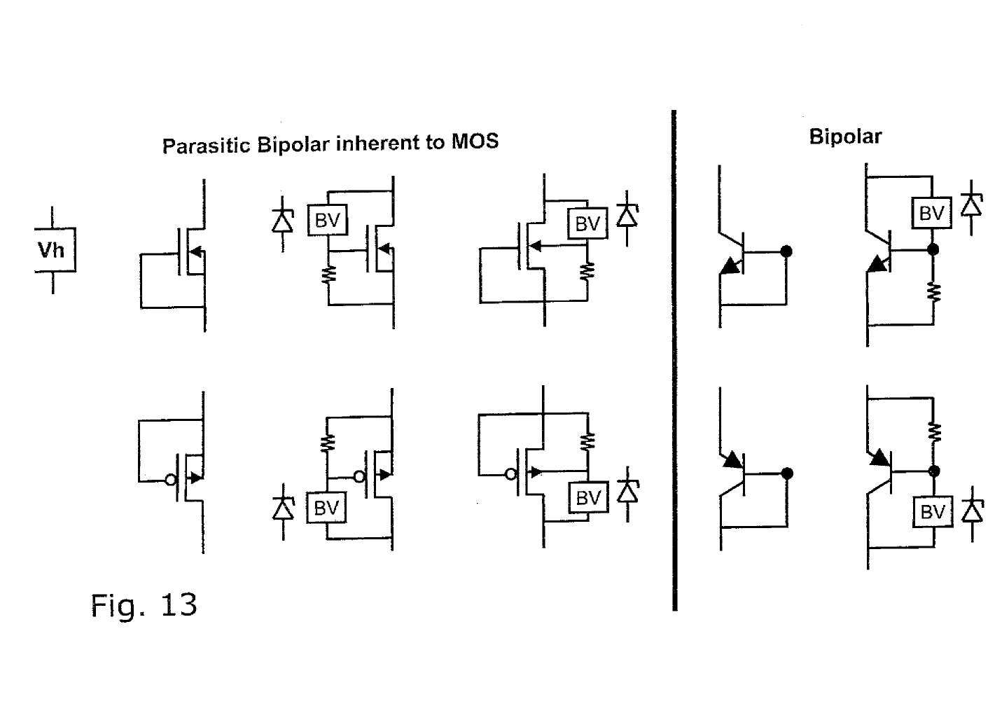

According to an embodiment, (low & high-voltage) bipolar transistors are connected to in series with the SCR. Those bipolar transistors can be parasitic in nature, i.e. inherent to MOS transistors such as an NPN within an NMOS, or can be pure bipolar elements. Possible Vh series element structures to increase the SCR holding voltage are schematically illustrated in FIG. 13.

One design aspect of this technique is the trigger voltage of the added series element(s). In one embodiment (parasitic) NPNs often show a snapback under ESD operation. As a known technique, these elements require ballast resistance to be incorporated into the drain (collector) and/or source (emitter), respectively, to generate a uniform current conduction under ESD and allow for scalable ESD device performance. This ballast resistance is for instance formed within a silicide-blocked drain of MOS transistors and occupies a substantial amount of area compared to the rest of the transistor. By lowering the snapback trigger voltage, this ballast resistance and as a result the related area can be significantly reduced. Reducing the snapback trigger voltage can be achieved by adding trigger/breakdown elements biasing the gate, or bulk or bipolar base during ESD at a lower breakdown voltage compared to the actual drain-bulk or collector-base breakdown of the (parasitic) bipolar. Alternatively, as an area efficient breakdown implementation a (zener) diode can be integrated directly into the MOS drain. Here, a zener or a typical ESD implant can be utilized to reduce the trigger voltage of an NMOS for instance.

As a result the snapback trigger voltage will be reduced ultimately to the holding voltage of the bipolar device. Such gate-coupled or bulk-/base-coupled schemes are illustrated in FIG. 13 with a breakdown BV device (e.g., a zener diode) coupling through a resistor (external or parasitic well resistance) to the corresponding nodes to be biased during ESD.

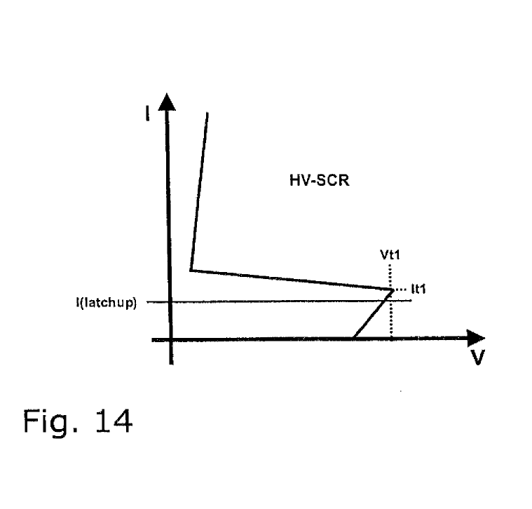

Another technique of enhancing the wrong-trigger robustness of the SCR during normal operation, is to increase the trigger current It1 of the SCR above the level of latch-up current injection I(latch-up). This concept is visualized in the schematic SCR IV curve of FIG. 14.

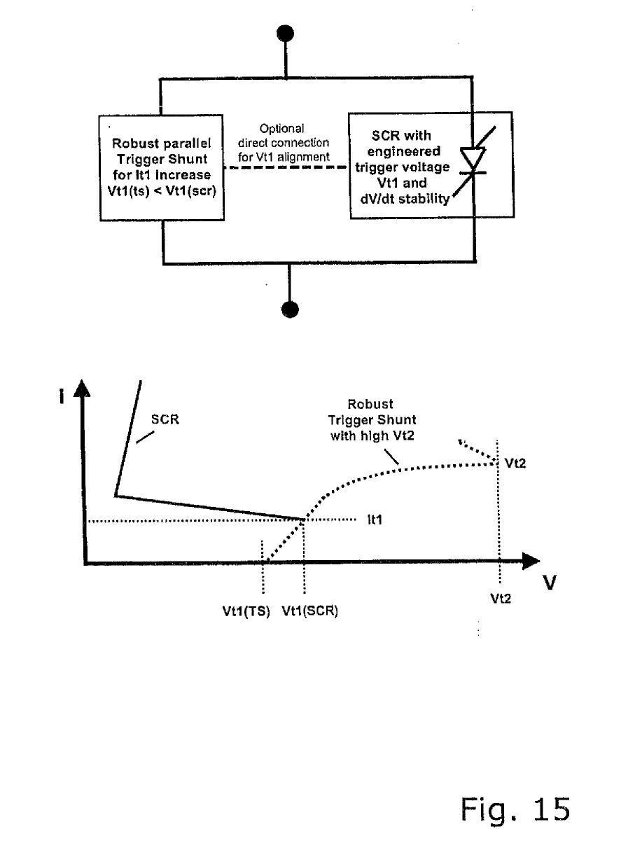

One embodiment for increasing the SCR trigger current is depicted in the schematic diagram in FIG. 15. Here a parallel robust trigger current shunt TS turns on at Vt1(TS) below the SCR trigger voltage Vt1(SCR). As a result the trigger shunt TS initially conducts the ESD stress current. Reaching Vt1(SCR) the SCR triggers at a certain increased trigger current It1(SCR). TS and SCR can be fully decoupled in this configuration. Optionally, the trigger voltage can be aligned by direct coupling of the trigger schemes in TS and SCR, respectively to design for Vt1(TS)<Vt1(SCR). It is still important to ensure that the SCR itself is sufficiently robust against transient disturbances, e.g. noise, dV/dt, or substrate currents. Moreover, the parallel shunt has to be sufficiently robust not being damaged during an ESD event. This means that the TS failure voltage Vt2(TS) must be larger than the SCR trigger voltage Vt1(SCR): Vt2(TS)>Vt1(SCR) as indicated FIG. 15 (bottom).

Advantages of the trigger current increase as described above include:
1. The SCR trigger current can be independently adjusted by the parallel TS without change of SCR core avoiding any detrimental impact on the SCR behavior. Another technique for instance uses small SCR shunt resistances within the SCR. This can cause significant trigger and ESD conduction issues due to the deteriorated SCR bipolar gains.
2. Straight-forward tuning of SCR trigger current It1:
   a) By increasing/decreasing the parallel shunt TS e.g., in width, the SCR trigger current It1(SCR) can be increased/decreased
   b) By increasing/decreasing the trigger voltage delta Vt1(TS)−Vt1(SCR), the SCR trigger current It1(SCR) current can be increased/decreased

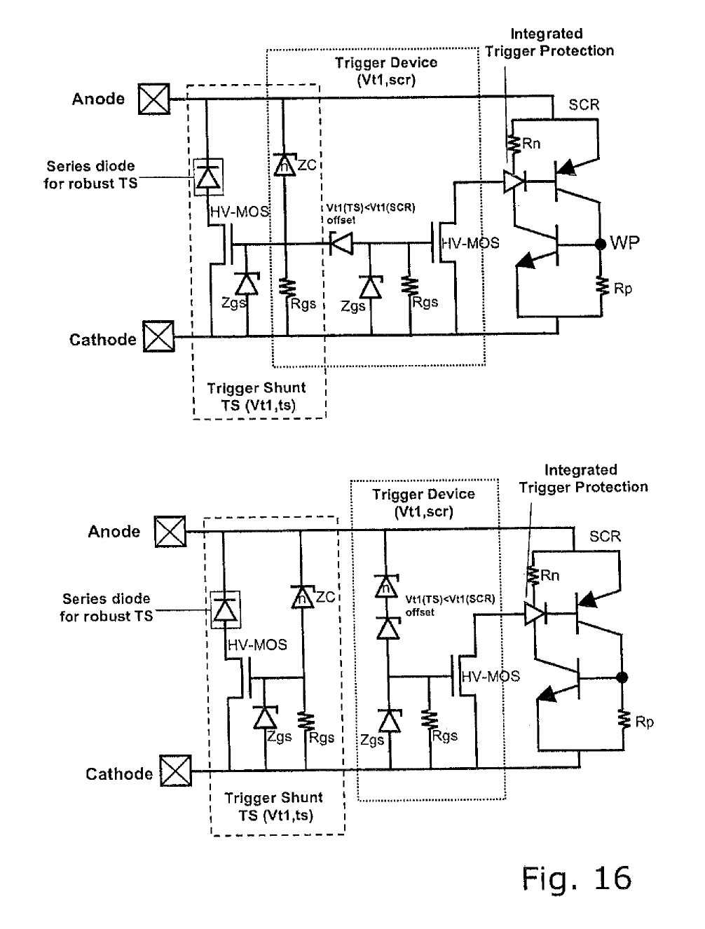

FIG. 16 illustrates two example embodiments for the general scheme in FIG. 11. The SCR in this embodiment is ESD triggered by a zener-diode chain (n+1 diodes in series) biasing the gate of a HV-MOS transistor through a resistor Rgs (Zgs is an optional zener gate protection diode). The SCR trigger mechanism has been explained above.

The parallel trigger shunt is formed by the same technique but with one zener diode less in the trigger chain (i.e. n diodes), thus creating the required offset of a zener breakdown Vt1(TS)−Vt1(SCR)˜BVzener (e.g., 4-7V). The TS has an external trigger protection (here a pn reverse diode) in series to keep the HV-MOS within the transient SOA without inherent parasitic NPN triggering.

The parallel TS and SCR can be
a) without any coupling in between with independent trigger voltage alignment by zener chains (cf. FIG. 16, top) or
b) with a direct connection due to the trigger zener chain for coupled trigger voltage alignment (cf. FIG. 16, bottom)

Different embodiment for robust TS with sufficiently large Vt2(TS) are possible e.g., by stacking MOS and/or bipolar transistors and/or diodes.

The above described SCR trigger schemes may be applied to plain CMOS technology, wherein the base material is the substrate or wherein the base material is the substrate while Pwell can be isolated by a deep-Nwell (triple-well process). The above described SCR trigger schemes may also be applied to Silicon-on-Insulator technology with an insulation layer (e.g., SiO₂) isolating the a) wells from the base material or b) base material (e.g., Epi) from a substrate. The above described SCR trigger schemes may further be applied to Bipolar-CMOS-DMOS technology with (at least one) buried layer (i.e. high doping deep-well) separating the base material (e.g., Epi) from a substrate.

The embodiments described above allow for reliable high-voltage SCR triggering by
a) Integration of high-voltage ESD trigger elements into the SCR circuit without trigger damage (potentially critical competitive current conduction action with the SCR) during the ESD event in one embodiment if HV-NMOS based transistors are applied. Those are often prone to parasitic NPN triggering and immediate subsequent ESD damage.
b) Transient trigger stability under normal operation conditions, i.e. to keep the SCR off also during high noise and fast slews rates (cf. automotive applications) despite of capacitive coupling to the relatively large high-voltage trigger device (with high capacitance)
c) Increased SCR trigger current and/or holding voltage while still keeping the excellent transient ESD clamping capabilities.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1-15. (canceled)

16. An integrated circuit, comprising:
a protected circuit;
a silicon controlled rectifier including a sequence of a first p-type region, a second n-type region, a third p-type region and a fourth n-type region, wherein the first p-type region is electrically coupled to the protected circuit;
a first pn junction diode including a first semiconductor zone and one of the second n-type region and the third p-type region as a second semiconductor zone, wherein a conductivity type of the first semiconductor zone is opposite to the conductivity type of the second semiconductor zone, and the first semiconductor zone adjoins the one element of the second n-type region and the third p-type region and is spaced apart from the other one element of the second n-type region and the third p-type region; and
a first trigger circuit electrically coupled to the first semiconductor zone.

17. The integrated circuit of claim 16, wherein
the second n-type region includes an n-well adjacent to a surface of an active semiconductor area of the silicon controlled rectifier;
the third p-type region includes a p-well adjacent to the surface and the n-well;
the first p-type region is arranged in the n-well and is adjacent to the surface; and
the fourth n-type region is arranged in the p-well and is adjacent to the surface.

18. The integrated circuit of claim 16, wherein the first semiconductor zone is arranged in the second semiconductor zone and is adjacent to a surface of an active semiconductor area of the silicon controlled rectifier.

19. The integrated circuit of claim 16, wherein a junction between the first semiconductor zone and the second semiconductor zone is parallel to a surface of an active semiconductor area of the silicon controlled rectifier.

20. The integrated circuit of claim 16, wherein a junction between the first semiconductor zone and the second semiconductor zone is rather perpendicular than parallel to a surface of an active semiconductor area of the silicon controlled rectifier.

21. The integrated circuit of claim 16, further comprising
a first external resistor arranged outside of an active semiconductor area of the silicon controlled rectifier, wherein the first external resistor is electrically coupled between the first p-type region and the second n-type region.

22. The integrated circuit of claim 16, further comprising
a second external resistor arranged outside of an active semiconductor area of the silicon controlled rectifier, wherein the second external resistor is electrically coupled between the third p-type region and the fourth n-type region.

23. The integrated circuit of claim 16, further comprising
at least one second pn junction diode including a first semiconductor zone and one of the group of the second n-type region and the third p-type region as a second semiconductor zone, wherein a conductivity type of the first semiconductor zone is opposite to the conductivity type of the second semiconductor zone; and
a second trigger circuit electrically coupled to the first semiconductor zone.

24. The integrated circuit of claim 16, wherein the first trigger circuit includes one or a chain of pn junctions, wherein the one or the chain of pn junctions include at least one or a combination of elements of the group including pn diode, bipolar transistor and parasitic MOS bipolar transistor.

25. The integrated circuit of claim 16, wherein the first trigger circuit includes a MOS transistor and a gate biasing circuit electrically coupled to a gate of the MOS transistor, or a bipolar or parasitic MOS bipolar transistor and a base biasing circuit electrically coupled to a base of the bipolar or parasitic MOS bipolar transistor.

26. The integrated circuit of claim 16, further comprising:
a trigger shunt circuit connected parallel to the SCR, wherein
the trigger shunt circuit is electrically coupled to the first trigger circuit; and wherein
a trigger voltage Vt1[SCR] of the silicon controlled rectifier and a turn-on voltage Vt1[TS] of the trigger shunt circuit satisfy Vt1[TS]<Vt1[SCR].

27. The integrated circuit of claim 16, wherein the first trigger circuit is electrically coupled between the second n-type region and the third p-type region.

28. The integrated circuit of claim 16, further comprising at least one of the group of an MOS transistor, a bipolar transistor and a parasitic MOS bipolar transistor connected in series with the silicon controlled rectifier for increasing a holding voltage.

29. The integrated circuit of claim 28, further comprising at least one of the group of a trigger circuit electrically coupled to a gate of the MOS transistor and a trigger circuit electrically coupled to a base of the bipolar or parasitic MOS bipolar transistor.

30. The integrated circuit of claim 28, further comprising a trigger region adjoining a drain region of the MOS transistor and/or a collector region of the bipolar or parasitic MOS bipolar transistor, wherein a net doping of a bulk region of the MOS transistor or a base region of the bipolar or parasitic MOS bipolar transistor is increased in the trigger region for decreasing a breakdown voltage of a bulk to drain junction of the MOS transistor or a base to collector junction of the bipolar or parasitic MOS bipolar transistor.
